(19) United States
(12) Patent Application Publication
(10) Pub. No.: US 2026/0262415 A1
(43) Pub. Date: Sep. 3, 2026

(54) DISPLAY APPARATUS AND FABRICATION METHOD FOR DISPLAY APPARATUS

(71) Applicants: Hefei Visionox Technology Co., Ltd., Hefei (CN); Visionox Technology Inc., Kunshan (CN)

(72) Inventors: Wenyu ZENG, Hefei (CN); Peng QIN, Kunshan (CN)

(73) Assignees: Hefei Visionox Technology Co., Ltd., Hefei (CN); Visionox Technology Inc., Kunshan (CN)

(21) Appl. No.: 19/420,745

(22) Filed: Dec. 16, 2025

(30) Foreign Application Priority Data
Feb. 28, 2025 (CN) 202510244417.0

(51) Int. Cl. H10K 59/80; H10K 59/12

(52) U.S. Cl. CPC H10K 59/8723; H10K 59/1201; H10K 59/8792

(57) ABSTRACT

The present application discloses a display apparatus and a fabrication method for a display apparatus. The display apparatus includes: a display panel including a substrate, an isolation structure, and a light-emitting device, the isolation structure being disposed on one side of the substrate and enclosing an isolation opening, and the light-emitting device being at least partially disposed within the isolation opening; a cover plate disposed on a light-exiting side of the display panel; and a light-shielding structure disposed on a side of the cover plate facing the display panel, where an orthographic projection of the light-shielding structure on the substrate and an orthographic projection of the isolation structure on the substrate enclose an alignment gap.

### CROSS-REFERENCE TO RELATED APPLICATIONS

The present application claims priority to the Chinese Patent Application NO. 202510244417.0, filed on Feb. 28, 2025, and the entire contents of the aforementioned application are hereby incorporated by reference in its entirety.

### FIELD

The present application relates to the field of display technology, and in particular to a display apparatus and a fabrication method for a display apparatus.

### BACKGROUND

Organic light-emitting diodes (OLEDs) and flat panel display apparatuses based on technologies such as light-emitting diodes (LEDs) have been widely used in various consumer electronics such as mobile phones, televisions, notebook computers, and desktop computers, and predominate in display apparatuses thanks to their advantages such as high image quality, energy efficiency, slim design, and a wide range of applications. During the fabrication of conventional display panels, light-emitting pixel patterning is usually implemented by means of a fine metal mask (FMM). FMM technology is mature and has rich experience in mass production. However, FMM technology also has problems such as limited accuracy, high development costs, and long development cycle. Mask-free technology eliminates the limitations of conventional OLED processes on display size, resolution, and other screen performances, and offers advantages of high performance, full-size coverage, and agile delivery. Reference can be made to relevant contents of the mask-free technology recited in Chinese patents CN118251982A, CN115666161A, CN116648095A, CN117062489A, CN117580403A, CN118678743A, CN118660490A, CN118678724A, CN118678806A, CN118742084A and CN118946184A.

However, the process performance of current OLED display products needs to be improved.

### SUMMARY

Embodiments of the present application provide a display apparatus and a fabrication method for a display apparatus, which are intended to facilitate the alignment between a cover plate and a display panel in the display apparatus.

An embodiment of a present application provides a display apparatus. The display apparatus includes: a display panel including a substrate, an isolation structure, and a light-emitting device, the isolation structure being disposed on one side of the substrate and enclosing a plurality of isolation openings, and the light-emitting device being at least partially disposed within the plurality of isolation openings; a cover plate disposed on a light-exiting side of the display panel; and a light-shielding structure disposed on a side of the cover plate facing the display panel, where an orthographic projection of the light-shielding structure on the substrate and an orthographic projection of the isolation structure on the substrate enclose an alignment gap.

According to an embodiment of the present application, a plurality of alignment gaps are formed, and the plurality of alignment gaps are spaced apart along a periphery of the orthographic projection of the isolation structure on the substrate, or the orthographic projection of the light-shielding structure on the substrate is spaced apart from the orthographic projection of the isolation structure on the substrate.

According to an embodiment of the present application, the orthographic projection of the light-shielding structure on the substrate is spaced apart from the orthographic projection of the isolation structure on the substrate, and the orthographic projection of the light-shielding structure on the substrate surrounds the orthographic projection of the isolation structure on the substrate, and the alignment gap is annular.

According to any one of the foregoing embodiments of the present application, the display apparatus has an active area and a non-active area, the isolation structure extending from the active area to the non-active area, both the light-emitting device and the isolation opening being located in the active area, and the light-shielding structure being located in the non-active area.

According to any one of the foregoing embodiments of the present application, the isolation structure further encloses a plurality of first functional openings located in the non-active area, the display apparatus further including a functional device at least partially located within the plurality of first functional openings, and the functional device and the light-emitting device being at least partially disposed in the same layer and made of the same material.

According to any one of the foregoing embodiments of the present application, the light-emitting device includes a first electrode, a light-emitting functional layer located on a side of the first electrode facing away from the substrate, and a second electrode located on a side of the light-emitting functional layer facing away from the substrate; and the functional device includes a first functional structure, a second functional structure located on a side of the first functional structure facing away from the substrate, and a third functional structure located on a side of the second functional structure facing away from the substrate, where the first functional structure and the first electrode are disposed in the same layer and made of the same material, and/or the second functional structure and the light-emitting functional layer are disposed in the same layer and made of the same material, and/or the third functional structure and the second electrode are disposed in the same layer and made of the same material.

According to any one of the foregoing embodiments of the present application, the display apparatus further includes an auxiliary structure disposed on one side of the substrate, an orthographic projection of the auxiliary structure on the substrate being at least partially between the orthographic projection of the isolation structure on the substrate and the orthographic projection of the light-shielding structure on the substrate, and a reflectivity of the auxiliary structure being greater than that of at least a film layer structure in the isolation structure.

According to any one of the foregoing embodiments of the present application, the isolation structure includes a first isolation portion and a second isolation portion located on a side of the first isolation portion facing away from the substrate, the reflectivity of the auxiliary structure being greater than that of the second isolation portion.

According to any one of the foregoing embodiments of the present application, a material of the auxiliary structure includes silver, and/or a material of the second isolation portion includes titanium.

According to any one of the foregoing embodiments of the present application, the auxiliary structure and part of the film layer structure in the light-emitting device are disposed in the same layer and made of the same material.

According to any one of the foregoing embodiments of the present application, the light-emitting device includes a first electrode, a light-emitting functional layer located on a side of the first electrode facing away from the substrate, and a second electrode located on a side of the light-emitting functional layer facing away from the substrate, the auxiliary structure and the first electrode being disposed in the same layer and made of the same material.

According to any one of the foregoing embodiments of the present application, the orthographic projection of the auxiliary structure on the substrate does not overlap the orthographic projection of the isolation structure on the substrate.

According to any one of the foregoing embodiments of the present application, the orthographic projection of the auxiliary structure on the substrate surrounds the orthographic projection of the isolation structure on the substrate.

According to any one of the foregoing embodiments of the present application, an edge of the orthographic projection of the auxiliary structure on the substrate is in contact with an edge of the orthographic projection of the isolation structure on the substrate, or the orthographic projection of the auxiliary structure on the substrate is spaced apart from the orthographic projection of the isolation structure on the substrate.

According to any one of the foregoing embodiments of the present application, the orthographic projection of the auxiliary structure on the substrate is spaced apart from the orthographic projection of the light-shielding structure on the substrate.

According to any one of the foregoing embodiments of the present application, the orthographic projection of the light-shielding structure on the substrate surrounds the orthographic projection of the auxiliary structure on the substrate.

According to any one of the foregoing embodiments of the present application, the display apparatus has an active area and a non-active area, the isolation structure further enclosing a plurality of first functional openings located in the non-active area, and the display apparatus further including a functional device at least partially located within the plurality of first functional openings, where the functional device includes a first functional structure, a second functional structure located on a side of the first functional structure facing away from the substrate, and a third functional structure located on a side of the second functional structure facing away from the substrate, the first functional structure of at least one functional device being reused as the auxiliary structure.

According to any one of the foregoing embodiments of the present application, the display apparatus has an active area and a non-active area, both the light-emitting device and the isolation opening being located in the active area, the light-shielding structure being located in the non-active area, and in a direction from the active area toward the non-active area, a size of the alignment gap being not less than 20 μm.

According to any one of the foregoing embodiments of the present application, the isolation structure includes a first isolation portion and a second isolation portion located on a side of the first isolation portion facing away from the substrate, the second isolation portion protruding from the first isolation portion toward the isolation opening.

According to any one of the foregoing embodiments of the present application, a material of the isolation structure includes a conductive material, and the light-emitting device includes a first electrode, a light-emitting functional layer located on a side of the first electrode facing away from the substrate, and a second electrode located on a side of the light-emitting functional layer facing away from the substrate, the second electrode being electrically connected to the isolation structure.

According to any one of the foregoing embodiments of the present application, the isolation structure further includes a conductive portion disposed on a side of the first isolation portion facing the substrate, the conductive portion protruding from the first isolation portion toward the isolation opening, and the second electrode being connected to the conductive portion.

An embodiment of the present application further provides a display apparatus having an active area and a non-active area. The display apparatus includes: a display panel including a substrate, an isolation structure, and a light-emitting device, the isolation structure being disposed on one side of the substrate and enclosing a plurality of isolation openings, and the light-emitting device being at least partially disposed within the plurality of isolation openings; a cover plate disposed on a light-exiting side of the display panel; and a light-shielding structure disposed on a side of the cover plate facing the display panel, where the isolation structure extends from the active area to the non-active area, both the light-emitting device and the isolation opening being located in the active area, the light-shielding structure being located in the non-active area, and an orthographic projection of the light-shielding structure on the substrate and an orthographic projection of the isolation structure on the substrate enclosing an alignment gap.

According to an embodiment of the present application, a plurality of alignment gaps are formed, and the plurality of alignment gaps are spaced apart along a periphery of the orthographic projection of the isolation structure on the substrate, or the orthographic projection of the light-shielding structure on the substrate is spaced apart from the orthographic projection of the isolation structure on the substrate.

According to an embodiment of the present application, the orthographic projection of the light-shielding structure on the substrate is spaced apart from the orthographic projection of the isolation structure on the substrate, and the orthographic projection of the light-shielding structure on the substrate surrounds the orthographic projection of the isolation structure on the substrate, and the alignment gap is annular.

According to any one of the foregoing embodiments of the present application, the isolation structure further encloses a plurality of first functional openings located in the non-active area, the display apparatus further including a functional device at least partially located within the plurality of first functional openings, and the functional device and the light-emitting device being at least partially disposed in the same layer and made of the same material.

According to any one of the foregoing embodiments of the present application, the light-emitting device includes a first electrode, a light-emitting functional layer located on a side of the first electrode facing away from the substrate, and a second electrode located on a side of the light-emitting functional layer facing away from the substrate; and the functional device includes a first functional structure, a second functional structure located on a side of the first functional structure facing away from the substrate, and a third functional structure located on a side of the second functional structure facing away from the substrate, where the first functional structure and the first electrode are disposed in the same layer and made of the same material, and/or the second functional structure and the light-emitting functional layer are disposed in the same layer and made of the same material, and/or the third functional structure and the second electrode are disposed in the same layer and made of the same material.

According to any one of the foregoing embodiments of the present application, the display apparatus further includes an auxiliary structure disposed on one side of the substrate, an orthographic projection of the auxiliary structure on the substrate being at least partially between the orthographic projection of the isolation structure on the substrate and the orthographic projection of the light-shielding structure on the substrate, and a reflectivity of the auxiliary structure being greater than that of at least a film layer structure in the isolation structure.

According to any one of the foregoing embodiments of the present application, the isolation structure includes a first isolation portion and a second isolation portion located on a side of the first isolation portion facing away from the substrate, the reflectivity of the auxiliary structure being greater than that of the second isolation portion.

According to any one of the foregoing embodiments of the present application, a material of the auxiliary structure includes silver, and/or a material of the second isolation portion includes titanium.

According to any one of the foregoing embodiments of the present application, the auxiliary structure is located in the non-active area.

According to any one of the foregoing embodiments of the present application, the auxiliary structure and part of the film layer structure in the light-emitting device are disposed in the same layer and made of the same material.

According to any one of the foregoing embodiments of the present application, the light-emitting device includes a first electrode, a light-emitting functional layer located on a side of the first electrode facing away from the substrate, and a second electrode located on a side of the light-emitting functional layer facing away from the substrate, the auxiliary structure and the first electrode being disposed in the same layer and made of the same material.

According to any one of the foregoing embodiments of the present application, the orthographic projection of the auxiliary structure on the substrate does not overlap the orthographic projection of the isolation structure on the substrate.

According to any one of the foregoing embodiments of the present application, the orthographic projection of the auxiliary structure on the substrate surrounds the orthographic projection of the isolation structure on the substrate.

According to any one of the foregoing embodiments of the present application, an edge of the orthographic projection of the auxiliary structure on the substrate is in contact with an edge of the orthographic projection of the isolation structure on the substrate, or the orthographic projection of the auxiliary structure on the substrate is spaced apart from the orthographic projection of the isolation structure on the substrate.

According to any one of the foregoing embodiments of the present application, the orthographic projection of the auxiliary structure on the substrate is spaced apart from the orthographic projection of the light-shielding structure on the substrate.

According to any one of the foregoing embodiments of the present application, the orthographic projection of the light-shielding structure on the substrate surrounds the orthographic projection of the auxiliary structure on the substrate.

According to any one of the foregoing embodiments of the present application, the isolation structure further encloses a plurality of first functional openings located in the active area, the display apparatus further including a functional device at least partially located within the plurality of first functional openings, the functional device including a first functional structure, a second functional structure located on a side of the first functional structure facing away from the substrate, and a third functional structure located on a side of the second functional structure facing away from the substrate, and the first functional structure of at least one functional device being reused as the auxiliary structure.

According to any one of the foregoing embodiments of the present application, in a direction from the active area toward the non-active area, a size of the alignment gap is not less than 20 μm.

According to any one of the foregoing embodiments of the present application, the isolation structure includes a first isolation portion and a second isolation portion located on a side of the first isolation portion facing away from the substrate, the second isolation portion protruding from the first isolation portion toward the isolation opening.

According to any one of the foregoing embodiments of the present application, a material of the isolation structure includes a conductive material, and the light-emitting device includes a first electrode, a light-emitting functional layer located on a side of the first electrode facing away from the substrate, and a second electrode located on a side of the light-emitting functional layer facing away from the substrate, the second electrode being electrically connected to the isolation structure.

According to any one of the foregoing embodiments of the present application, the isolation structure further includes a conductive portion disposed on a side of the first isolation portion facing the substrate, the conductive portion protruding from the first isolation portion toward the isolation opening, and the second electrode being connected to the conductive portion.

An embodiment of a second aspect of the present application provides a fabrication method for a display apparatus. The method includes:

fabricating a display panel including a substrate, an isolation structure, and a light-emitting device, the isolation structure being disposed on one side of the substrate and enclosing a plurality of isolation openings, and the light-emitting device being at least partially disposed within the plurality of isolation openings;

obtaining, by using an optical probe, an edge position of the isolation structure and an edge position of a light-shielding structure located on one side of a cover plate;

adjusting a position of the cover plate and an orthographic projection of the light-shielding structure on the substrate and an orthographic projection of the isolation structure on the substrate enclose a desired alignment gap; and

bonding the cover plate to a light-exiting side of the display panel.

An embodiment of the second aspect of the present application further provides a fabrication method for a display apparatus. The method includes:

fabricating a display panel including a substrate, an isolation structure, a light-emitting device, and an auxiliary structure, both the isolation structure and the auxiliary structure being disposed on one side of the substrate, the isolation structure enclosing a plurality of isolation openings, the light-emitting device being at least partially disposed within the plurality of isolation openings, and an orthographic projection of an edge of the auxiliary structure on the substrate at least partially not overlapping an orthographic projection of the isolation structure on the substrate;

obtaining, by using an optical probe, an edge position of the auxiliary structure and an edge position of a light-shielding structure located on one side of a cover plate;

adjusting a position of the cover plate and an orthographic projection of the light-shielding structure on the substrate and the orthographic projection of the isolation structure on the substrate enclose a desired alignment gap; and

bonding the cover plate to a light-exiting side of the display panel.

In the display apparatus provided by the embodiments of the present application, the display apparatus includes the display panel, the cover plate, and the light-shielding structure. The display panel includes the substrate, the isolation structure, and the light-emitting device. The isolation structure is disposed on one side of the substrate and encloses the plurality of isolation openings. The light-emitting device is at least partially disposed within the plurality of isolation openings. The isolation structure may be used to participate in defining sub-pixels of the display panel. The cover plate is disposed on the light-exiting side of the display panel and may be used to protect the display panel. The light-shielding structure is disposed on the side of the cover plate facing the display panel and may be used to block light.

By configuring the orthographic projection of the light-shielding structure on the substrate and the orthographic projection of the isolation structure on the substrate to enclose the alignment gap, during the alignment and bonding process of the display panel and the cover plate, the shape and size of the alignment gap can be obtained by using the optical probe, thereby facilitating the alignment between the cover plate and the display panel in the display apparatus.

### BRIEF DESCRIPTION OF THE DRAWINGS

In order to describe the embodiments of the present application more clearly, the drawings required for illustration of the embodiments of the present application will be briefly introduced below. Apparently, the drawings as described below are only for part of the embodiments of the present application, and other drawings can also be obtained from these drawings.

FIG. 1 is a schematic structural diagram of a display apparatus according to an embodiment of the present application;

FIG. 2 is a schematic structural diagram of an isolation structure and a light-shielding structure according to an embodiment of the present application;

FIG. 3 is a schematic structural diagram of an isolation structure and a light-shielding structure according to another embodiment of the present application;

FIG. 4 is a partial cross-sectional view of a display apparatus according to an embodiment of the present application;

FIG. 5 is a schematic structural diagram of a display apparatus according to another embodiment of the present application;

FIG. 6 is a partial cross-sectional view of a display apparatus according to another embodiment of the present application;

FIG. 7 is a partial cross-sectional view of a display apparatus according to still another embodiment of the present application;

FIG. 8 is a partial cross-sectional view of a display apparatus according to yet another embodiment of the present application;

FIG. 9 is a partial cross-sectional view of a display apparatus according to a further embodiment of the present application;

FIG. 10 is a partial cross-sectional view of a display apparatus according to a further embodiment of the present application;

FIG. 11 is a schematic flowchart of a fabrication method for a display apparatus according to an embodiment of the present application; and

FIG. 12 is a schematic flowchart of a fabrication method for a display apparatus according to another embodiment of the present application.

### LIST OF REFERENCE SIGNS

10. Display panel;

100. Substrate; 110. Base substrate; 120. First insulating layer; 130. Second insulating layer; 140. Third insulating layer; 150. Drive circuit; 151. Transistor; 151a. Gate; 151b.

Source and drain; 152. Storage capacitor; 152a. First electrode plate; 152b. Second electrode plate;

200. Pixel define layer; 210. Pixel defining portion; 220. Pixel opening; 230. Second functional opening;

300. Isolation structure; 300a. Isolation opening; 300b. First functional opening; 310. First isolation portion; 320. Second isolation portion; 330. Conductive portion;

400. Light-emitting device; 410. First electrode; 420. Light-emitting functional layer; 430. Second electrode;

500. Functional device; 510. First functional structure; 520. Second functional structure; 530. Third functional structure;

600. Auxiliary structure;

700. Encapsulation layer; 710. First encapsulation layer; 720. Second encapsulation layer; 730. Third encapsulation layer;

20. Cover plate;

30. Light-shielding structure;

G. Alignment gap;

AA. Active area; NA. Non-active area; NA1. First non-active area; NA2. Second non-active area.

### DETAILED DESCRIPTION OF THE EMBODIMENTS

Features and exemplary embodiments in various aspects of the present application will be described in detail below. In order to make the embodiments of the present application clearer, the present application will be further described in detail below with reference to the accompanying drawings and some embodiments. It should be understood that the embodiments described herein are merely configured to explain the present application and are not configured to limit the present application. Embodiments of the present application may be implemented without part of these specific details. The following description of the embodiments is merely to provide a better understanding of the present application by illustrating examples of the present application.

It should be noted that, herein, relational terms such as "first" and "second" are only used to distinguish one entity or operation from another entity or operation, and do not necessarily require or imply that such an actual relationship or order exists between these entities or operations. Furthermore, the terms "comprises", "includes" or any other variant thereof are intended to cover non-exclusive inclusion, and a process, method, object or device including a series of elements not only includes those elements, but further includes other elements not explicitly listed, or further includes elements inherent to such process, method, object or device. Without further limitation, an element limited by "comprising/including ..." does not exclude other identical elements existing in the process, the method, the object, or the device that includes the element.

It should be understood that in the description of the structure of a component, a layer or region referred as being located "above" or "over" another layer or region may be directly on the other layer or region, or there may be other layers or regions between the layer or region and the other layer or region. Moreover, when the component is turned over, the layer or region is located "below" or "under" the other layer or region.

In order to solve the above problems, the embodiments of the present application provide a display panel, a display apparatus, and a fabrication method for a display panel. Various embodiments of the display panel, the display apparatus, and the fabrication method for a display panel will be described below with reference to the accompanying drawings.

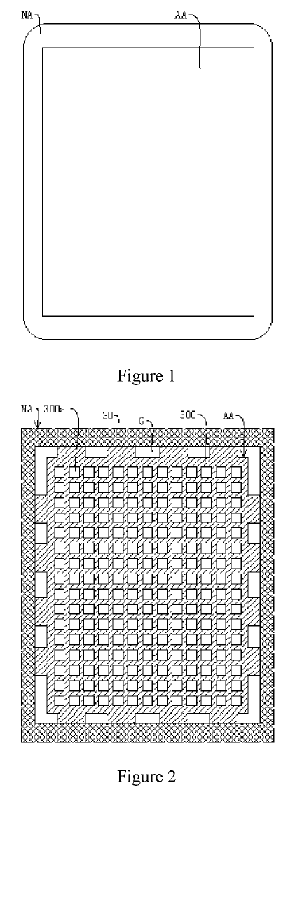

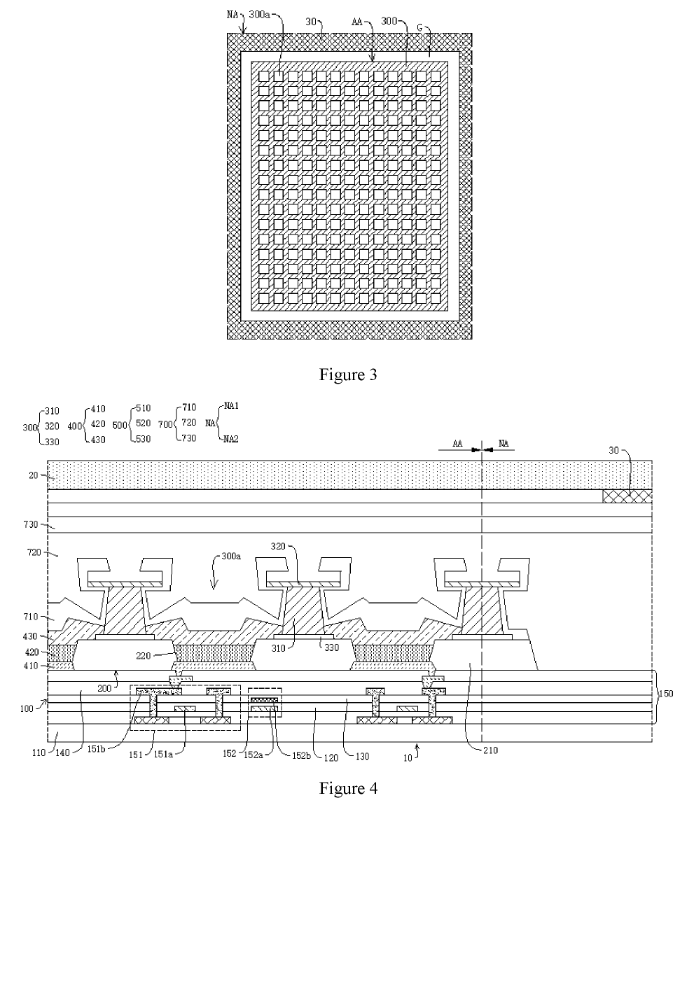

FIG. 1 is a schematic structural diagram of a display apparatus according to an embodiment of the present application. FIG. 2 is a schematic structural diagram of an isolation structure 300 and a light-shielding structure 30 according to an embodiment of the present application. FIG. 3 is a schematic structural diagram of an isolation structure 300 and a light-shielding structure 30 according to another embodiment of the present application. FIG. 4 is a partial cross-sectional view of a display apparatus according to an embodiment of the present application.

As shown in FIGS. 1 to 4, an embodiment of a present application provides a display apparatus. The display apparatus includes: a display panel 10 including a substrate 100, an isolation structure 300, and a light-emitting device 400, the isolation structure 300 being disposed on one side of the substrate 100 and enclosing an isolation opening 300a, and the light-emitting device 400 being at least partially disposed within the isolation opening 300a; a cover plate 20 disposed on a light-exiting side of the display panel 10; and a light-shielding structure 30 disposed on a side of the cover plate 20 facing the display panel 10, where an orthographic projection of the light-shielding structure 30 on the substrate 100 and an orthographic projection of the isolation structure 300 on the substrate 100 enclose an alignment gap G.

In the display apparatus provided by this embodiment of the present application, the display apparatus includes the display panel 10, the cover plate 20, and the light-shielding structure 30. The display panel 10 includes the substrate 100, the isolation structure 300, and the light-emitting device 400.

In one embodiment, the substrate 100 may be configured in various forms. For example, the substrate 100 may include a base substrate 110 and a drive circuit 150 disposed on a side of the base substrate 110 facing the light-emitting device 400. For example, the drive circuit 150 may include a transistor 151, a storage capacitor 152, and drive signal lines for connecting the devices. The transistor 151 may include a semiconductor, a gate 151a, and source and drain 151b. The storage capacitor 152 may include a first electrode plate 152a and a second electrode plate 152b.

In one embodiment, the substrate 100 may include a first insulating layer 120, a second insulating layer 130, and a third insulating layer 140 that are stacked. As an example, the gate 151a and the first electrode plate 152a may be located on a side of the first insulating layer 120 facing the base substrate 110, the second electrode plate 152b may be located between the first insulating layer 120 and the second insulating layer 130, and the source and drain 151b may be located between the second insulating layer 130 and the third insulating layer 140.

In one embodiment, the light-emitting device 400 includes a first electrode 410, a light-emitting functional layer 420 located on a side of the first electrode 410 facing away from the substrate 100, and a second electrode 430 located on a side of the light-emitting functional layer 420 facing away from the substrate 100.

In one embodiment, the light-emitting functional layer 420 may include a hole injection layer (HIL), a hole transport layer (HTL), a light-emitting structure, an electron injection layer (EIL), and an electron transport layer (ETL).

In one embodiment, the first electrode 410 and the second electrode 430 may serve as pixel electrodes of the display panel 10. One of the first electrode 410 and the second electrode 430 may serve as an anode, and the other may serve as a cathode, and the light-emitting functional layer 420 is driven to emit light. The embodiments of the present application are described by taking the example in which the first electrode 410 is the anode of the display panel 10 and the second electrode 430 is the cathode of the display panel 10.

The isolation structure 300 is disposed on one side of the substrate 100 and encloses the isolation opening 300a, the light-emitting device 400 is at least partially disposed within the isolation opening 300a, and the isolation structure 300 may be used to participate in defining sub-pixels of the display panel 10.

In one embodiment, the display apparatus may have an active area AA and a non-active area NA. Both the light-emitting device 400 and the isolation opening 300a are located in the active area AA, and the part of the display apparatus in the active area AA may be used for light-emitting display.

In one embodiment, the isolation structure 300 may include a first isolation portion 310 and a second isolation portion 320 located on a side of the first isolation portion 310 facing away from the substrate 100, the second isolation portion 320 protruding from the first isolation portion 310 toward the isolation opening 300a, and during the fabrication of the light-emitting device 400 of the display panel 10, part of the material of the light-emitting device 400 (e.g., the material of the light-emitting functional layer 420 and the material of the second electrode 430) can be directly evaporated over the entire surface. The second isolation portion 320 can block at least part of the material used to fabricate the light-emitting device 400, to isolate the material of the light-emitting device 400 between adjacent sub-pixels. This facilitates the formation of a plurality of spaced-apart light-emitting devices 400 that are spaced apart and located within different isolation openings 300a. Therefore, during the fabrication of the light-emitting devices 400 of the display panel 10, it is unnecessary to provide a high-precision mask. For example, this eliminates the need for using a fine metal mask (FMM) during evaporation of the material of the light-emitting functional layer 420, thereby effectively reducing the production and fabrication cost of the display panel 10.

In one embodiment, the material of the first isolation portion 310 may include aluminum, and the material of the second isolation portion 320 may include titanium, and an appropriate etch selectivity can be achieved between the first isolation portion 310 and the second isolation portion 320, facilitating the etching of the material of the isolation structure 300 to form a morphology where "the second isolation portion 320 protrudes from the first isolation portion 310 toward the isolation opening 300a".

In one embodiment, the material of the isolation structure 300 includes a conductive material, and the second electrode 430 is electrically connected to the isolation structure 300, and the second electrodes 430 of adjacent light-emitting devices 400 can be electrically connected through the isolation structure 300, thereby facilitating the control of the second electrode 430. For example, the second electrode 430 may be connected to the first isolation portion 310.

In one embodiment, the isolation structure 300 further includes a conductive portion 330 disposed on a side of the first isolation portion 310 facing the substrate 100. The conductive portion 330 protrudes from the first isolation portion 310 toward the isolation opening 300a. The second electrode 430 is connected to the conductive portion 330. By configuring the conductive portion 330 to protrude from the first isolation portion 310 toward the isolation opening 300a, the conductive portion 330 can have a large area for connection with the second electrode 430, thereby facilitating the electrical connection between the second electrode 430 and the isolation structure 300.

In one embodiment, the material of the conductive portion 330 may include molybdenum, which provides good electrical conductivity for the conductive portion 330 while also achieving an appropriate etch selectivity ratio between the first isolation portion 310 and the conductive portion 330, facilitating the etching of the material of the isolation structure 300 to form a morphology where "the conductive portion 330 protrudes from the first isolation portion 310 toward the isolation opening 300a".

In one embodiment, the display panel 10 may further include a pixel define layer 200 disposed on one side of the substrate 100. The pixel define layer 200 may include a pixel defining portion 210 and a pixel opening 220 enclosed by the pixel defining portion 210. The pixel opening 220 may be in communication with the isolation opening 300a. Part of the structure of the light-emitting device 400 may be located within the pixel opening 220, and another part of the structure of the light-emitting device 400 may be located within the isolation opening 300a. The pixel define layer 200 can also participate in defining sub-pixels of the display panel 10.

For example, the second electrode 430 and the light-emitting functional layer 420 of the light-emitting device 400 may extend from the pixel opening 220 to a side of the pixel defining portion 210 facing away from the substrate 100. That is, part of the second electrode 430 and the light-emitting functional layer 420 of the light-emitting device 400 may be located within the pixel opening 220, and another part of the second electrode 430 and the light-emitting functional layer 420 of the light-emitting device 400 may be located within the isolation opening 300a. The first electrode 410 of the light-emitting device 400 may be located between the pixel define layer 200 and the substrate 100. Part of the surface of the side of the first electrode 410 facing away from the substrate 100 may be exposed from the pixel opening 220 and connected to the light-emitting functional layer 420 within the pixel opening 220.

In one embodiment, a plurality of isolation openings 300a and a plurality of pixel openings 220 may be provided, and a single isolation opening 300a may be in communication with a single pixel opening 220.

In one embodiment, both the isolation structure 300 and the pixel define layer 200 may be mesh-shaped. Hollow regions in the mesh-shaped isolation structure 300 may form the isolation openings 300a, and the hollow regions in the mesh-shaped pixel define layer 200 may form the pixel openings 220.

In one embodiment, the relative position between the pixel defining portion 210 and the isolation structure 300 may be configured in various forms. For example, the isolation structure 300 may be disposed on the side of the pixel defining portion 210 facing away from the substrate 100, i.e., the isolation structure 300 may be disposed directly on the pixel defining portion 210. Alternatively, for example, the pixel defining portion 210 may be provided with a groove structure (not shown in the figure), and at least part of the isolation structure 300 may be located within the groove structure, preventing the isolation structure 300 from having an excessive height relative to the substrate 100, thereby effectively reducing the thickness of the display panel 10. For ease of description, the following embodiments are described by taking the example in which the isolation structure 300 is disposed on the side of the pixel defining portion 210 facing away from the substrate 100.

In one embodiment, the display panel 10 may further include an encapsulation layer 700 disposed on a side of the light-emitting device 400 and the isolation structure 300 facing away from the substrate 100. The encapsulation layer 700 may be used to encapsulate the light-emitting device 400, thereby improving the structural stability of the display apparatus.

For example, the encapsulation layer 700 may include a first encapsulation layer 710, a second encapsulation layer 720 disposed on a side of the first encapsulation layer 710 facing away from the substrate 100, and a third encapsulation layer 730 disposed on a side of the second encapsulation layer 720 facing away from the substrate 100. The materials of the first encapsulation layer 710 and the third encapsulation layer 730 may include inorganic materials, and the first encapsulation layer 710 and the third encapsulation layer 730 can effectively reduce the impact of moisture on the operation of the light-emitting device 400. The material of the second encapsulation layer 720 may include an organic material, allowing the second encapsulation layer 720 to achieve good flowability during the fabrication of the display panel 10, and the surface of the side of the second encapsulation layer 720 facing away from the substrate 100 can achieve good planarity, thereby facilitating the formation of subsequent film layers.

As an example, the first encapsulation layer 710 and the third encapsulation layer 730 may be fabricated by a chemical vapor deposition (CVD) process. The second encapsulation layer 720 may be fabricated by an inkjet printing (IJP) process.

It can be understood that the display panel 10 may further include structures, such as a touch electrode, a color filter layer, an optical adhesive, and a polarizer disposed on a side of the encapsulation layer 700 facing away from the substrate 100, which are not limited in the present application.

The cover plate 20 is disposed on the light-exiting side of the display panel 10 and may be used to protect the display panel 10. The light-shielding structure 30 disposed on the side of the cover plate 20 facing the display panel 10 may be used to block light.

In one embodiment, the cover plate 20 being disposed on the light-exiting side of the display panel 10 may refer to the cover plate 20 being disposed outside the display panel 10 and located on a side of the light-emitting device 400 facing away from the substrate 100.

In one embodiment, the light-shielding structure 30 may be located in the non-active area NA and can effectively limit light leakage in the non-active area NA of the display apparatus.

In one embodiment, a material of the light-shielding structure 30 may include an opaque material, allowing the light-shielding structure 30 to effectively block light.

In one embodiment, the light-shielding structure 30 may block light by absorbing the light. For example, the material of the light-shielding structure 30 may include a black ink material, allowing the light-shielding structure 30 to effectively block light by absorbing the light.

By configuring the orthographic projection of the light-shielding structure 30 on the substrate 100 and the orthographic projection of the isolation structure 300 on the substrate 100 to enclose the alignment gap G, during the alignment and bonding process of the display panel 10 and the cover plate 20, the shape and size of the alignment gap G can be obtained by using an optical probe, thereby facilitating the alignment between the cover plate 20 and the display panel 10 in the display apparatus.

For example, in the display apparatus fabricated in the present application, by configuring the orthographic projection of the light-shielding structure 30 on the substrate 100 and the orthographic projection of the isolation structure 300 on the substrate 100 to enclose the alignment gap G, during the alignment and bonding process of the display panel 10 and the cover plate 20, the shape and size of the gap between the light-shielding structure 30 and the isolation structure 300 can be obtained first by using the optical probe, and then the position of the cover plate 20 can be adjusted and the shape and size of the gap between the light-shielding structure 30 and the isolation structure 300 can meet desired requirements. That is, the position of the cover plate 20 can be adjusted and the orthographic projection of the light-shielding structure 30 on the substrate 100 and the orthographic projection of the isolation structure 300 on the substrate 100 enclose an alignment gap G having desired shape and size, thereby facilitating the alignment between the cover plate 20 and the display panel 10 in the display apparatus.

In the embodiments of the present application, the number and shape of the alignment gaps G may be configured in various manners.

In some embodiments, as shown in FIG. 2, a plurality of alignment gaps G are formed, and the plurality of alignment gaps G are spaced apart along the periphery of the orthographic projection of the isolation structure 300 on the substrate 100.

In one embodiment, an orthographic projection of part of an outer edge of the isolation structure 300 on the substrate 100 may be spaced apart from the orthographic projection of the light-shielding structure 30 on the substrate 100, and an orthographic projection of another part of the outer edge of the isolation structure 300 on the substrate 100 may be in contact with the orthographic projection of the light-shielding structure 30 on the substrate 100 (as shown in FIG. 2), or the orthographic projection of another part of the outer edge of the isolation structure 300 on the substrate 100 may be within the orthographic projection of the light-shielding structure 30 on the substrate 100 (not shown in the figure). The alignment gap G may be formed in a spacing between the orthographic projection of part of the outer edge of the isolation structure 300 on the substrate 100 and the orthographic projection of the light-shielding structure 30 on the substrate 100.

For example, the outer edge of the isolation structure 300 may have a sawtooth shape, and the alignment gap G may be formed between adjacent sawteeth.

In one embodiment, the alignment gap G have various shapes, which are not limited in the present application. FIG. 2 illustrates an embodiment in which the alignment gap G is square.

In these embodiments, by providing a plurality of alignment gaps G that are spaced apart along the periphery of the orthographic projection of the isolation structure 300 on the substrate 100, the alignment precision between the cover plate 20 and the display panel 10 can be improved. For example, during the alignment and bonding process of the display panel 10 and the cover plate 20, the position of the cover plate 20 can be adjusted and the shape and size of each alignment gap G can meet desired requirements, thereby facilitating more precise alignment between the cover plate 20 and the display panel 10 in the display apparatus.

Alternatively, in some other embodiments, as shown in FIG. 3, the orthographic projection of the light-shielding structure 30 on the substrate 100 may be spaced apart from the orthographic projection of the isolation structure 300 on the substrate 100.

In one embodiment, the orthographic projection of the light-shielding structure 30 on the substrate 100 surrounds the orthographic projection of the isolation structure 300 on the substrate 100, and the alignment gap G is annular.

In these embodiments, by configuring the orthographic projection of the light-shielding structure 30 on the substrate 100 to be spaced apart from the orthographic projection of the isolation structure 300 on the substrate 100, the alignment gap G can have a larger size, which is advantageous for reducing the alignment difficulty between the cover plate 20 and the display panel 10. For example, during the alignment and bonding process of the display panel 10 and the cover plate 20, the position of the cover plate 20 can be adjusted and the shape and size of part of the alignment gap G at specific positions (e.g., at left and right bezels, or at top and bottom bezels) meet desired requirements, thereby facilitating easier alignment between the cover plate 20 and the display panel 10 in the display apparatus.

For ease of description, the following embodiments are described by taking the example in which the orthographic projection of the light-shielding structure 30 on the substrate 100 is spaced apart from the orthographic projection of the isolation structure 300 on the substrate 100.

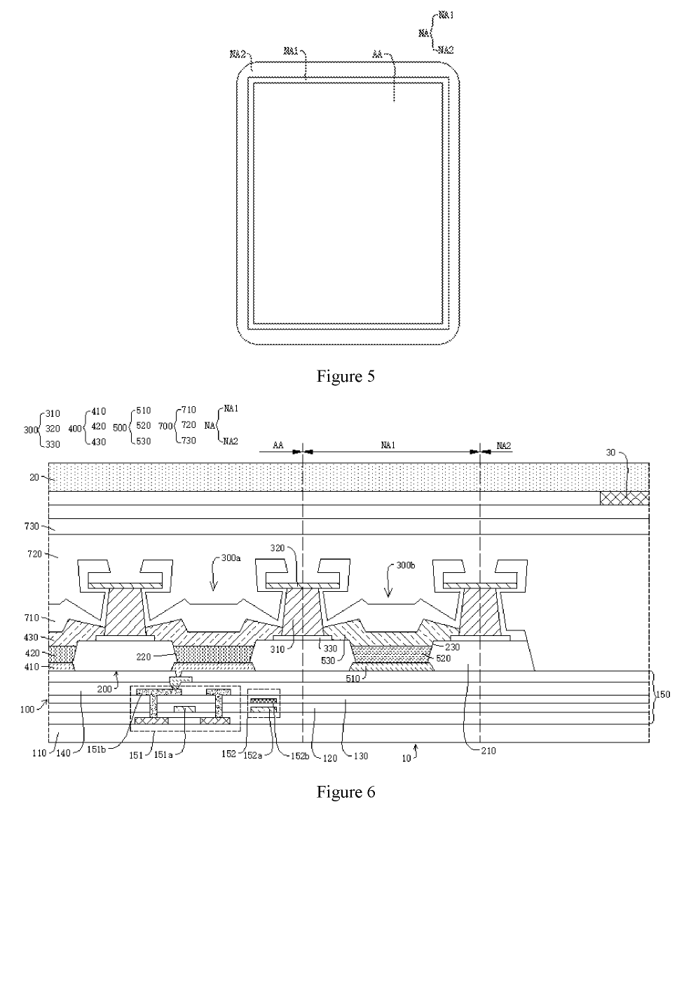

FIG. 5 is a schematic structural diagram of a display apparatus according to another embodiment of the present application. FIG. 6 is a partial cross-sectional view of a display apparatus according to another embodiment of the present application.

As shown in FIGS. 5 and 6, in some embodiments, the isolation structure 300 may extend from the active area AA into the non-active area NA. The part of the isolation structure 300 extending into the non-active area NA may be used to suppress interference between signals from the touch electrode in the display panel 10 and signals from the drive circuit 150 in the substrate 100, and the part of the isolation structure 300 extending into the non-active area NA allows an etching material accumulated outside the isolation structure 300 during the etching process of the display panel 10 to be far from the isolation opening 300a. This can effectively reduce the concentration of the etching material around the isolation opening 300a on a side near the non-active area NA during the fabrication of the display panel 10, thereby effectively reducing the over-etching effect of the etching material on the morphology of the isolation structure 300 around the isolation opening 300a in the active area AA during the fabrication of the display panel 10.

In some embodiments, the isolation structure 300 further encloses a first functional opening 300b in the non-active area NA, the display apparatus further including a functional device 500 at least partially located within the first functional opening 300b, and the functional device 500 and the light-emitting device 400 being disposed in the same layer and made of the same material.

For example, the non-active area NA includes a first non-active area NA1 and a second non-active area NA2. The first non-active area NA1 is located between the active area and the second non-active area NA2. The first functional opening 300b may be located in the first non-active area NA1, and the light-shielding structure 30 may be located in the second non-active area NA2.

In one embodiment, the functional device 500 includes a first functional structure 510, a second functional structure 520 located on a side of the first functional structure 510 facing away from the substrate 100, and a third functional structure 530 located on a side of the second functional structure 520 facing away from the substrate 100.

In one embodiment, the first functional structure 510 and the first electrode 410 are disposed in the same layer and made of the same material, and/or the second functional structure 520 and the light-emitting functional layer 420 are disposed in the same layer and made of the same material, and/or the third functional structure 530 and the second electrode 430 are disposed in the same layer and made of the same material.

For example, the first functional structure 510 may be located between the pixel define layer 200 and the substrate 100. The pixel defining portion 210 located on the side of the first functional structure 510 facing away from the substrate 100 may enclose a second functional opening 230 that is in communication with the first functional opening 300b. Part of the second functional structure 520 and the third functional structure 530 may be located within the first functional opening 300b, and another part of the second functional structure 520 and the third functional structure 530 may be located within the second functional opening 230. Part of the surface of the side of the first functional structure 510 facing away from the substrate 100 may be exposed from the second functional opening 230 and connected to the second functional structure 520 within the second functional opening 230.

Alternatively, for example, an orthographic projection of the first functional structure 510 on the substrate 100 is within an orthographic projection of the pixel defining portion 210 on the substrate 100 (not shown in the figure). The pixel defining portion 210 located on the side of the first functional structure 510 facing away from the substrate 100 may not enclose the second functional opening 230 described in the foregoing embodiment. Both the second functional structure 520 and the third functional structure 530 are located within the functional opening, and both the second functional structure 520 and the third functional structure 530 are located on the side of the pixel defining portion 210 facing away from the substrate 100.

In one embodiment, during the use of the display panel 10, the functional device 500 may not participate in light-emitting display, i.e., the functional device 500 may not receive a drive current from the drive circuit 150.

In these embodiments, the functional device 500 disposed in correspondence with the second functional opening 230 may serve as a dummy sub-pixel of the display panel 10. Both the functional device 500 and the isolation structure 300 located in the non-active area NA and around the functional device 500 may be used to suppress interference between signals from the touch electrode in the display panel 10 and signals from the drive circuit 150 in the substrate 100, and used to reduce the over-etching effect of the etching material on the morphology of the isolation structure 300 around the isolation opening 300a in the active area AA during the fabrication of the display panel 10.

In addition, by configuring the functional device 500 and the light-emitting device 400 to be at least partially disposed in the same layer and made of the same material, film layer structures in the functional device 500 can be fabricated simultaneously with corresponding film layer structures in the light-emitting device 400, thereby effectively improving the fabrication efficiency of the display panel 10. For example, the first functional structure 510 may be fabricated simultaneously with the first electrode 410, the second functional structure 520 may be fabricated simultaneously with the light- emitting functional layer 420, and the third functional structure 530 may be fabricated simultaneously with the second electrode 430.

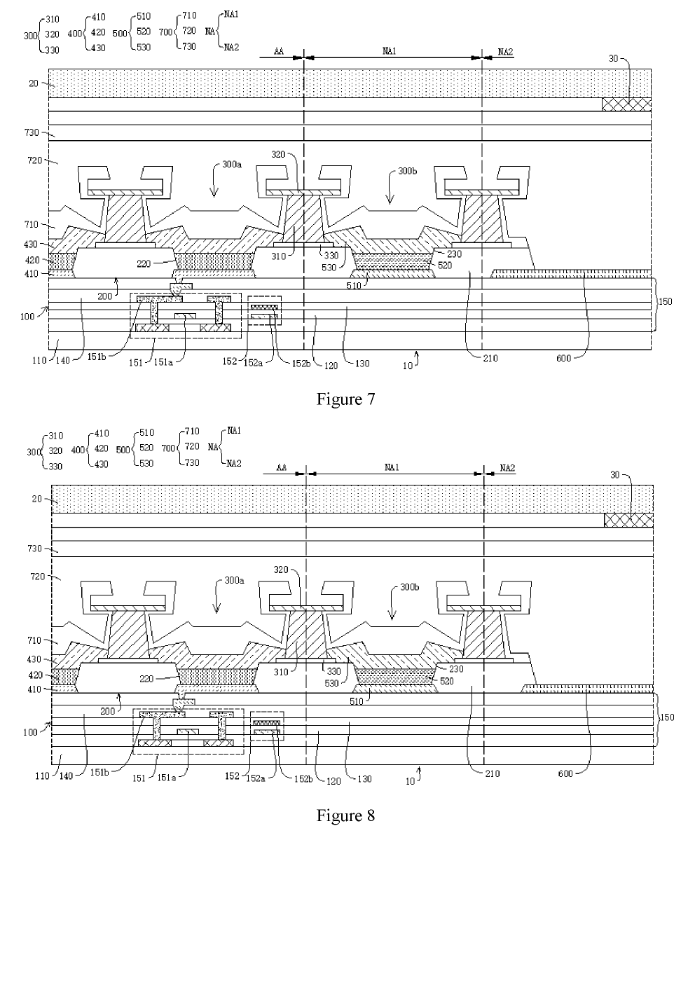

FIG. 7 is a partial cross-sectional view of a display apparatus according to still another embodiment of the present application.

In some embodiments, the display apparatus further includes an auxiliary structure 600 disposed on one side of the substrate 100, an orthographic projection of the auxiliary structure 600 on the substrate 100 being at least partially located between the orthographic projection of the isolation structure 300 on the substrate 100 and the orthographic projection of the light-shielding structure 30 on the substrate 100, and a reflectivity of the auxiliary structure 600 being greater than that of at least a film layer structure in the isolation structure 300.

In one embodiment, a material of the auxiliary structure 600 includes silver.

In one embodiment, the auxiliary structure 600 is located in the non-active area NA. For example, the auxiliary structure 600 may be annular and surround the active area AA.

In these embodiments, by providing the auxiliary structure 600 with a high reflectivity between the isolation structure 300 and the light-shielding structure 30, when the shape and size of the alignment gap G are obtained by using an optical probe, the auxiliary structure 600 with a high reflectivity can appear as a high-brightness structure when imaged by the optical probe, and the isolation structure 300 with a low reflectivity can appear as a low- brightness structure when imaged by the optical probe. The brightness contrast between the isolation structure 300 and the auxiliary structure 600 facilitates the optical probe in obtaining the shape and size of the alignment gap G, thereby facilitating the alignment between the cover plate 20 and the display panel 10 in the display apparatus.

For example, when the light-shielding structure 30 blocks light by absorbing the light, i.e., when the material of the light-shielding structure 30 includes a light-absorbing material, the light-shielding structure 30 can also appear as a low-brightness structure when imaged by the optical probe. That is, the brightness contrast between the auxiliary structure 600 and the light-shielding structure 30 also facilitates the optical probe in obtaining the shape and size of the alignment gap G, thereby facilitating the alignment between the cover plate 20 and the display panel 10 in the display apparatus.

In some embodiments, the reflectivity of the auxiliary structure 600 being greater than that of at least the film layer structure in the isolation structure 300 may refer to the reflectivity of the auxiliary structure 600 being greater than that of the second isolation portion 320.

In these embodiments, when the reflectivity of the auxiliary structure 600 is configured to be greater than that of the second isolation portion 320, during the alignment between the cover plate 20 and the display panel 10, the optical probe can be disposed on the light-exiting side of the display panel 10, i.e., on a side of the second isolation portion 320 facing away from the substrate 100, and the isolation structure 300 can appear as a low-brightness structure when imaged by the optical probe due to the impact of the second isolation portion 320 with a low reflectivity near the optical probe.

In the embodiments of the present application, the position of the auxiliary structure 600 may be configured in various manners.

In some embodiments, the auxiliary structure 600 and part of the film layer structure in the light-emitting device 400 are disposed in the same layer and made of the same material.

In one embodiment, the auxiliary structure 600 and the first electrode 410 are disposed in the same layer and made of the same material.

In these embodiments, by configuring the auxiliary structure 600 and part of the film layer structure in the light-emitting device 400 to be disposed in the same layer and made of the same material, e.g., by configuring the auxiliary structure 600 and the first electrode 410 to be disposed in the same layer and made of the same material, the fabrication of the auxiliary structure 600 can be completed simultaneously with the fabrication of the light-emitting device 400, thereby effectively improving the fabrication efficiency of the display panel 10.

In the embodiments of the present application, various methods are available for determining whether the alignment gap G is a desired alignment gap G by using an optical probe, i.e., various methods are available for determining whether the alignment gap G has desired shape and size by using an optical probe.

In some embodiments, during the alignment and bonding process of the display panel 10 and the cover plate 20, an edge position of the isolation structure 300 and an edge position of the light-shielding structure 30 can be directly obtained by using an optical probe (e.g., an illumination range of the optical probe may extend to the surface of a side of the isolation structure 300 facing away from the substrate 100, allowing the optical probe to effectively obtain the edge position of the isolation structure 300 and the edge position of the light-shielding structure 30). The position of the cover plate 20 can then be adjusted based on the edge position of the isolation structure 300 and the edge position of the light-shielding structure 30 obtained by using the optical probe, and the orthographic projection of the light-shielding structure 30 on the substrate 100 and the orthographic projection of the isolation structure 300 on the substrate 100 can enclose an alignment gap G having the desired shape and size, thereby facilitating the alignment between the cover plate 20 and the display panel 10 in the display apparatus.

Moreover, in these embodiments, since it is unnecessary to utilize edge positions of other structures to assist in positioning, a small spacing can be configured between the edge of the isolation structure 300 and the edge of the light-shielding structure 30, which is advantageous for narrowing the bezel of the display apparatus.

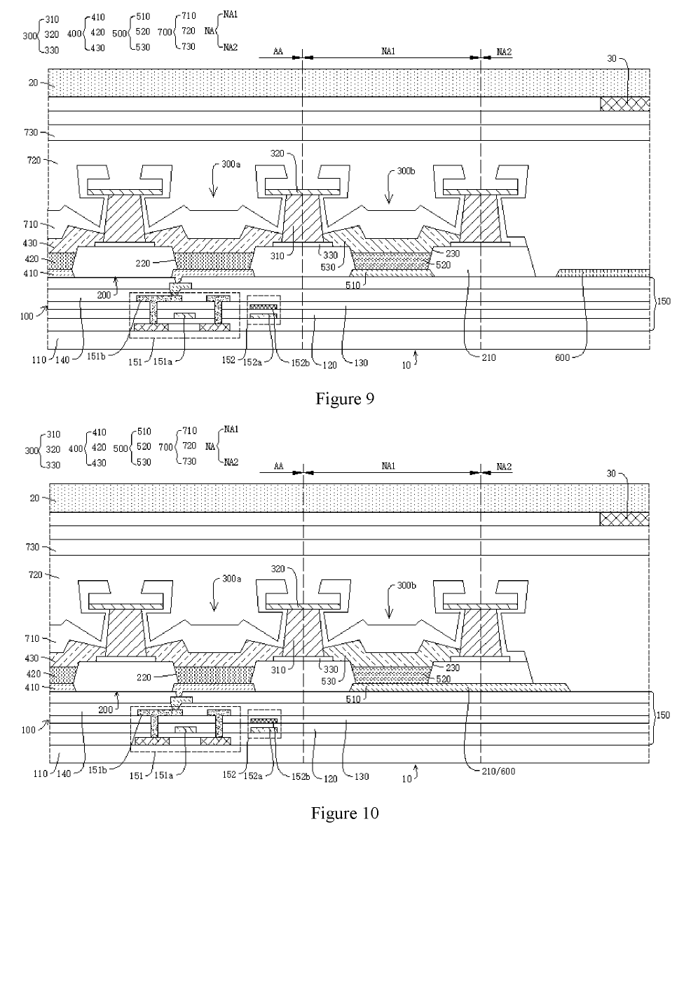

FIG. 8 is a partial cross-sectional view of a display apparatus according to yet another embodiment of the present application. FIG. 9 is a partial cross-sectional view of a display apparatus according to a further embodiment of the present application. FIG. 10 is a partial cross-sectional view of a display apparatus according to a further embodiment of the present application.

As shown in FIGS. 8 to 10, in some other embodiments, by appropriately configuring the relative positional relationship between the edge of the auxiliary structure 600 and the edge of the isolation structure 300, during the alignment and bonding process of the display panel 10 and the cover plate 20, an edge position of the auxiliary structure 600 and an edge position of the light-shielding structure 30 can be obtained by using an optical probe (e.g., an illumination range of the optical probe may extend to the surface of a side of the auxiliary structure 600 facing away from the substrate 100, allowing the optical probe to effectively obtain the edge position of the isolation structure 300 and the edge position of the light-shielding structure 30). The position of the cover plate 20 can then be adjusted based on the edge position of the auxiliary structure 600 and the edge position of the light-shielding structure 30 obtained by using the optical probe, and the alignment gap G in the fabricated display apparatus has the desired shape and size, thereby facilitating the alignment between the cover plate 20 and the display panel 10 in the display apparatus.

For ease of description, the following embodiments are described by taking the example in which "during the alignment and bonding process of the display panel 10 and the cover plate 20, the position of the cover plate 20 is adjusted based on the edge position of the auxiliary structure 600 and the edge position of the light-shielding structure 30 obtained by using an optical probe, and the alignment gap G in the fabricated display apparatus has the desired shape and size, thereby facilitating the alignment between the cover plate 20 and the display panel 10 in the display apparatus".

As shown in FIGS. 8 and 9, in some embodiments, the orthographic projection of the auxiliary structure 600 on the substrate 100 does not overlap the orthographic projection of the isolation structure 300 on the substrate 100.

In one embodiment, the orthographic projection of the auxiliary structure 600 on the substrate 100 may surround the orthographic projection of the isolation structure 300 on the substrate 100.

In one embodiment, as shown in FIG. 8, the edge of the orthographic projection of the auxiliary structure 600 on the substrate 100 is in contact with the edge of the orthographic projection of the isolation structure 300 on the substrate 100.

Alternatively, as shown in FIG. 9, the orthographic projection of the auxiliary structure 600 on the substrate 100 is spaced apart from the orthographic projection of the isolation structure 300 on the substrate 100.

For example, when the orthographic projection of the auxiliary structure 600 on the substrate 100 is spaced apart from the orthographic projection of the isolation structure 300 on the substrate 100, since the orthographic projection of the auxiliary structure 600 on the substrate 100 is at least partially located between the orthographic projection of the isolation structure 300 on the substrate 100 and the orthographic projection of the light-shielding structure 30 on the substrate 100, an orthographic projection of an edge of a side of the auxiliary structure 600 facing the isolation structure 300 on the substrate 100 is located between the orthographic projection of the isolation structure 300 on the substrate 100 and the orthographic projection of the light-shielding structure 30 on the substrate 100.

In these embodiments, when the orthographic projection of the auxiliary structure 600 on the substrate 100 does not overlap the orthographic projection of the isolation structure 300 on the substrate 100, during the alignment and bonding process of the display panel 10 and the cover plate 20, an edge position of the side of the auxiliary structure 600 facing the isolation structure 300 and an edge position of the light-shielding structure 30 can be obtained by using an optical probe. The position of the cover plate 20 can then be adjusted based on the edge position of the side of the auxiliary structure 600 facing the isolation structure 300 and the edge position of the light-shielding structure 30 obtained by using the optical probe, and the alignment gap G in the fabricated display apparatus has the desired shape and size, thereby facilitating the alignment between the cover plate 20 and the display panel 10 in the display apparatus.

As shown in FIG. 10, in some other embodiments, the orthographic projection of the auxiliary structure 600 on the substrate 100 is spaced apart from the orthographic projection of the light-shielding structure 30 on the substrate 100.

In one embodiment, the orthographic projection of the light-shielding structure 30 on the substrate 100 may surround the orthographic projection of the auxiliary structure 600 on the substrate 100.

For example, when the orthographic projection of the auxiliary structure 600 on the substrate 100 is spaced apart from the orthographic projection of the light-shielding structure 30 on the substrate 100, since the orthographic projection of the auxiliary structure 600 on the substrate 100 is at least partially located between the orthographic projection of the isolation structure 300 on the substrate 100 and the orthographic projection of the light-shielding structure 30 on the substrate 100, an orthographic projection of the edge of a side of the auxiliary structure 600 facing the light-shielding structure 30 on the substrate 100 is located between the orthographic projection of the isolation structure 300 on the substrate 100 and the orthographic projection of the light-shielding structure 30 on the substrate 100.

In these embodiments, when the orthographic projection of the auxiliary structure 600 on the substrate 100 is spaced apart from the orthographic projection of the light-shielding structure 30 on the substrate 100, during the alignment and bonding process of the display panel 10 and the cover plate 20, an edge position of the side of the auxiliary structure 600 facing the light-shielding structure 30 and an edge position of the light-shielding structure 30 can be obtained by using an optical probe. The position of the cover plate 20 may then be adjusted based on the edge position of the side of the auxiliary structure 600 facing the light-shielding structure 30 and the edge position of the light-shielding structure 30 obtained by using the optical probe, and the alignment gap G in the fabricated display apparatus has the desired shape and size, thereby facilitating the alignment between the cover plate 20 and the display panel 10 in the display apparatus.

In some embodiments, as shown in FIG. 10, when the orthographic projection of the auxiliary structure 600 on the substrate 100 is spaced apart from the orthographic projection of the light-shielding structure 30 on the substrate 100, the first functional structure 510 of at least one functional device 500 is reused as the auxiliary structure 600.

In one embodiment, the first functional structure 510 of the at least one functional device 500 being reused as the auxiliary structure 600 may mean that the first functional structure 510 of the at least one functional device 500 may extend toward the light-shielding structure 30 beyond the isolation structure 300. That is, an orthographic projection of an edge of a side of the first functional structure 510 of the at least one functional device 500 facing the light-shielding structure 30 on the substrate 100 may be located between the orthographic projection of the isolation structure 300 on the substrate 100 and the orthographic projection of the light-shielding structure 30 on the substrate 100.

For example, all first functional structures 510 of the functional devices 500 corresponding to the functional openings at the outermost periphery may be reused as the auxiliary structure 600.

In these embodiments, by reusing the first functional structure 510 of the at least one functional device 500 as the auxiliary structure 600, the fabrication of the auxiliary structure 600 can be completed simultaneously with the fabrication of the first functional structure 510, thereby effectively improving the fabrication efficiency of the display panel 10.

In some embodiments, in a direction from the active area AA toward the non-active area NA, the size of the alignment gap G is not less than 20 μm.

For example, in the direction from the active area AA toward the non-active area NA, the size of the alignment gap G may be 20 μm, 25 μm, 30 μm, 35 μm, 40 μm, 45 μm, 50 μm, 55 μm, or 60 μm.

In one embodiment, when the orthographic projection of the light-shielding structure 30 on the substrate 100 is spaced apart from the orthographic projection of the isolation structure 300 on the substrate 100, the size of the alignment gap G in the direction from the active area AA toward the non-active area NA may refer to a spacing between the orthographic projection of the light-shielding structure 30 on the substrate 100 and the orthographic projection of the isolation structure 300 on the substrate 100.

In these embodiments, by appropriately configuring the size of the alignment gap, it facilitates detection by the optical probe.

In some embodiments of the present application, by appropriately configuring a spacing between an orthographic projection of an inner wall of the isolation opening 300a on the substrate 100 and the orthographic projection of the light-shielding structure 30 on the substrate 100, the spacing between the orthographic projection of the inner wall of the isolation opening 300a on the substrate 100 and the orthographic projection of the light-shielding structure 30 on the substrate 100 can be prevented from being excessively large, thereby facilitating the reduction of the size of the non-active area NA and improving the display effect of the display apparatus, and the spacing between the orthographic projection of the inner wall of the isolation opening 300a on the substrate 100 and the orthographic projection of the light-shielding structure 30 on the substrate 100 can be prevented from being excessively small, thereby facilitating detection by the optical probe.

For example, the spacing between the orthographic projection of the inner wall of the isolation opening 300a on the substrate 100 and the orthographic projection of the light-shielding structure 30 on the substrate 100 may range from 200 μm to 300 μm, which is not specifically limited in the present application.

In one embodiment, when the spacing between the orthographic projection of the inner wall of the isolation opening 300a on the substrate 100 and the orthographic projection of the light-shielding structure 30 on the substrate 100 is a, and the size of the alignment gap G in the direction from the active area AA toward the non-active area NA is b, a space c available between the isolation opening 300a and the light-shielding structure 30 for arranging the functional openings meets: c=a-b.

Referring to FIGS. 1 to 10, an embodiment of the present application further provides a display apparatus having an active area AA and a non-active area NA. The display apparatus includes: a display panel 10 including a substrate 100, an isolation structure 300, and a light-emitting device 400, the isolation structure 300 being disposed on one side of the substrate 100 and enclosing an isolation opening 300a, and the light-emitting device 400 being at least partially disposed within the isolation opening 300a; a cover plate 20 disposed on a light-exiting side of the display panel 10; and a light-shielding structure 30 disposed on a side of the cover plate 20 facing the display panel 10, where the isolation structure 300 extends from the active area AA to the non-active area NA, both the light-emitting device 400 and the isolation opening 300a are located in the active area AA, the light-shielding structure 30 being located in the non-active area NA, and an orthographic projection of the light-shielding structure 30 on the substrate 100 and an orthographic projection of the isolation structure 300 on the substrate 100 enclose an alignment gap G.

In the display apparatus provided by this embodiment of the present application, the display apparatus includes the display panel 10, the cover plate 20, and the light-shielding structure 30. The display panel 10 includes the substrate 100, the isolation structure 300, and the light-emitting device 400. The isolation structure 300 is disposed on one side of the substrate 100 and encloses the isolation opening 300a, the light-emitting device 400 is at least partially disposed within the isolation opening 300a, and the isolation structure 300 may be used to participate in defining sub-pixels of the display panel 10. The display apparatus may have the active area AA and the non-active area NA. Both the light-emitting device 400 and the isolation opening 300a are located in the active area AA, and the part of the display apparatus in the active area AA may be used for light-emitting display.

The isolation structure 300 extends from the active area AA into the non-active area NA. The part of the isolation structure 300 extending into the non-active area NA may be used to suppress interference between signals from the touch electrode in the display panel 10 and signals from the drive circuit 150 in the substrate 100, and the part of the isolation structure 300 extending into the non-active area NA allows an etching material accumulated outside the isolation structure 300 during the etching process of the display panel 10 to be far from the isolation opening 300a. This can effectively reduce the concentration of the etching material around the isolation opening 300a on a side near the non-active area NA during the fabrication of the display panel 10, thereby effectively reducing the over-etching effect of the etching material on the morphology of the isolation structure 300 around the isolation opening 300a in the active area AA during the fabrication of the display panel 10.

The cover plate 20 is disposed on the light-exiting side of the display panel 10 and may be used to protect the display panel 10. The light-shielding structure 30 disposed on the side of the cover plate 20 facing the display panel 10 can effectively limit light leakage in the non-active area NA of the display apparatus.

By configuring the orthographic projection of the light-shielding structure 30 on the substrate 100 and the orthographic projection of the isolation structure 300 on the substrate 100 to enclose the alignment gap G, during the alignment and bonding process of the display panel 10 and the cover plate 20, the shape and size of the alignment gap G can be obtained by using an optical probe, thereby facilitating the alignment between the cover plate 20 and the display panel 10 in the display apparatus.

In one embodiment, a display panel 10 further provided by an embodiment of the present application may be the display panel 10 in any one of the foregoing embodiments. Therefore, the display panel 10 further provided by this embodiment of the present application may have the structure and beneficial effects of the display panel 10 in any one of the foregoing embodiments, which will not be described in detail in the present application.

For example, a fabrication method for the display panel 10 may be configured with reference to any one of the foregoing embodiments. For example, the substrate 100 may be the substrate 100 in any one of the foregoing embodiments. For example, the light-emitting device 400 may be the light-emitting device 400 in any one of the foregoing embodiments, and the light-emitting device 400 may include the first electrode 410, the light-emitting functional layer 420 and the second electrode 430 in any one of the foregoing embodiments. For example, the display apparatus may further include the functional device 500 in any one of the foregoing embodiments. For example, the isolation structure 300 may be the isolation structure 300 in any one of the foregoing embodiments, the isolation structure 300 may enclose the isolation opening 300a and the functional openings in any one of the foregoing embodiments, and the isolation structure 300 may include the first isolation portion 310, the second isolation portion 320, and the conductive portion 330 in any one of the foregoing embodiments. For example, the display apparatus may further include the auxiliary structure 600 in any one of the foregoing embodiments.

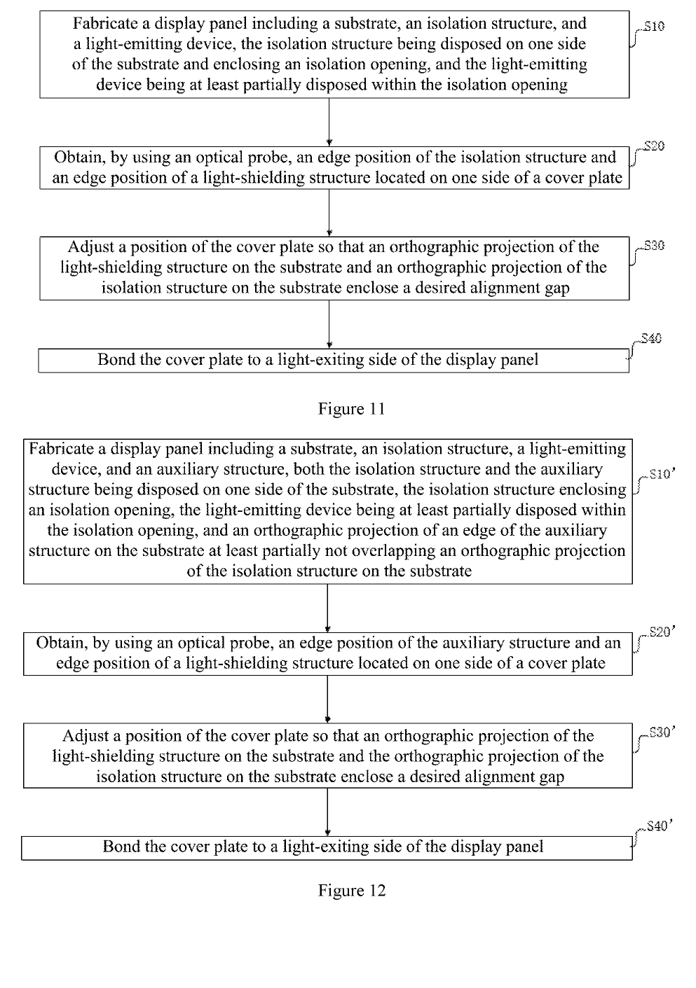

FIG. 11 is a schematic flowchart of a fabrication method for a display apparatus according to an embodiment of the present application.

Referring to FIG. 11 in conjunction with FIGS. 1 to 10, an embodiment of a second aspect of the present application provides a fabrication method for a display apparatus. The display apparatus fabricated by using the fabrication method may be the display apparatus provided by the embodiments of the first aspect above. The fabrication method includes the following steps.

Step S10: Fabricate a display panel 10 including a substrate 100, an isolation structure 300, and a light-emitting device 400, the isolation structure 300 being disposed on one side of the substrate 100 and enclosing an isolation opening 300a, and the light-emitting device 400 being at least partially disposed within the isolation opening 300a.

In one embodiment, the display panel 10 may be the display panel 10 in any one of the foregoing embodiments.

Step S20: Obtain, by using an optical probe, an edge position of the isolation structure 300 and an edge position of a light-shielding structure 30 located on one side of a cover plate 20.

In one embodiment, before step S20, the fabrication method may include: fabricating the light-shielding structure 30 on one side of the cover plate 20.

For example, an illumination range of the optical probe may extend to the surface of a side of the isolation structure 300 facing away from the substrate 100, allowing the optical probe to effectively obtain the edge position of the isolation structure 300 and the edge position of the light-shielding structure 30.

Step S30: Adjust the position of the cover plate 20 and an orthographic projection of the light-shielding structure 30 on the substrate 100 and an orthographic projection of the isolation structure 300 on the substrate 100 enclose a desired alignment gap G.

In one embodiment, the desired alignment gap G may refer to an alignment gap G with desired shape and size.

Step S40: Bond the cover plate 20 to a light-exiting side of the display panel 10.

In the fabrication method provided by this embodiment of the present application, by obtaining the edge position of the isolation structure 300 and the edge position of the light-shielding structure 30 located on one side of the cover plate 20 by using the optical probe in step S20, the position of the cover plate 20 can be adjusted in step S30 based on the edge position of the isolation structure 300 and the edge position of the light-shielding structure 30 obtained by using the optical probe, and the orthographic projection of the light-shielding structure 30 on the substrate 100 and the orthographic projection of the isolation structure 300 on the substrate 100 can enclose an alignment gap G having the desired shape and size, thereby facilitating the alignment between the cover plate 20 and the display panel 10 in the display apparatus.

FIG. 12 is a schematic flowchart of a fabrication method for a display apparatus according to another embodiment of the present application.

Referring to FIG. 12 in conjunction with FIGS. 1 to 10, an embodiment of the second aspect of the present application further provides a fabrication method for a display apparatus. The display apparatus fabricated by using the fabrication method may be the display apparatus provided by the embodiments of the first aspect above. The fabrication method includes the following steps.

Step S10': Fabricate a display panel 10 including a substrate 100, an isolation structure 300, a light-emitting device 400, and an auxiliary structure 600, both the isolation structure 300 and the auxiliary structure 600 being disposed on one side of the substrate 100, the isolation structure 300 enclosing an isolation opening 300a, the light- emitting device 400 being at least partially disposed within the isolation opening 300a, and an orthographic projection of an edge of the auxiliary structure 600 on the substrate 100 at least partially not overlapping an orthographic projection of the isolation structure 300 on the substrate 100.

In one embodiment, the display panel 10 may be the display panel 10 in any one of the foregoing embodiments.

In one embodiment, the orthographic projection of the edge of the auxiliary structure 600 on the substrate 100 at least partially not overlapping the orthographic projection of the isolation structure 300 on the substrate 100 may mean that an orthographic projection of at least part of the edge of the auxiliary structure 600 on the substrate 100 may be on a side of the orthographic projection of the isolation structure 300 on the substrate 100 away from an active area AA.

Step S20': Obtain, by using an optical probe, an edge position of the auxiliary structure 600 and an edge position of a light-shielding structure 30 located on one side of a cover plate 20.

In one embodiment, before step S20', the fabrication method may include: fabricating the light-shielding structure 30 on one side of the cover plate 20.

For example, an illumination range of the optical probe may extend to the surface of a side of the auxiliary structure 600 facing away from the substrate 100, allowing the optical probe to effectively obtain the edge position of the isolation structure 300 and the edge position of the light-shielding structure 30.

Step S30': Adjust the position of the cover plate 20 and an orthographic projection of the light-shielding structure 30 on the substrate 100 and the orthographic projection of the isolation structure 300 on the substrate 100 enclose a desired alignment gap G.

In one embodiment, the desired alignment gap G may refer to an alignment gap G with desired shape and size.

Step S40': Bond the cover plate 20 to a light-exiting side of the display panel 10.

In the fabrication method provided by this embodiment of the present application, by obtaining the edge position of the auxiliary structure 600 and the edge position of the light-shielding structure 30 located on one side of the cover plate 20 by using the optical probe in step S20', the position of the cover plate 20 can be adjusted in step S30' based on the edge position of the auxiliary structure 600 and the edge position of the light-shielding structure 30 obtained by using the optical probe, and the orthographic projection of the light-shielding structure 30 on the substrate 100 and the orthographic projection of the isolation structure 300 on the substrate 100 can enclose an alignment gap G having the desired shape and size, thereby facilitating the alignment between the cover plate 20 and the display panel 10 in the display apparatus.

The embodiments of the present application as described above neither set forth all the details, nor do they limit the present application to only the described specific embodiments. Apparently, many modifications and variations can be made in light of the above description. The embodiments are selected and described in this specification to better explain the principles and practical applications of the present application, good use of the present application can be made and modified and used the present application. The present application is limited only by the claims and all the scopes and equivalents thereof.

1. A display apparatus, comprising:
a display panel comprising a substrate, an isolation structure, and a light-emitting device, the isolation structure being disposed on one side of the substrate and enclosing a plurality of isolation openings, and the light-emitting device being at least partially disposed within the plurality of isolation openings;
a cover plate disposed on a light-exiting side of the display panel; and
a light-shielding structure disposed on a side of the cover plate facing the display panel,
wherein an orthographic projection of the light-shielding structure on the substrate and an orthographic projection of the isolation structure on the substrate enclose an alignment gap.

2. The display apparatus according to claim 1, wherein a plurality of alignment gaps are formed, and the plurality of alignment gaps are spaced apart along a periphery of the orthographic projection of the isolation structure on the substrate,
or the orthographic projection of the light-shielding structure on the substrate is spaced apart from the orthographic projection of the isolation structure on the substrate.

3. The display apparatus according to claim 1, wherein the display apparatus has an active area and a non-active area, the isolation structure extending from the active area to the non-active area, both the light-emitting device and the isolation opening being located in the active area, and the light-shielding structure being located in the non-active area.

4. The display apparatus according to claim 3, wherein the isolation structure further encloses a plurality of first functional openings located in the non-active area, the display apparatus further comprising a functional device at least partially located within the plurality of first functional openings, and the functional device and the light-emitting device being at least partially disposed in a same layer and made of a same material.

5. The display apparatus according to claim 1, wherein the display apparatus further comprises an auxiliary structure disposed on one side of the substrate, an orthographic projection of the auxiliary structure on the substrate being at least partially between the orthographic projection of the isolation structure on the substrate and the orthographic projection of the light-shielding structure on the substrate, and a reflectivity of the auxiliary structure being greater than that of at least a film layer structure in the isolation structure.

6. The display apparatus according to claim 5, wherein the auxiliary structure and part of the film layer structure in the light-emitting device are disposed in a same layer and made of a same material.

7. The display apparatus according to claim 5, wherein the orthographic projection of the auxiliary structure on the substrate does not overlap the orthographic projection of the isolation structure on the substrate.

8. The display apparatus according to claim 5, wherein the orthographic projection of the auxiliary structure on the substrate is spaced apart from the orthographic projection of the light-shielding structure on the substrate.

9. The display apparatus according to claim 1, wherein the display apparatus has an active area and a non-active area, both the light-emitting device and the isolation opening being located in the active area, the light-shielding structure being located in the non-active area, and in a direction from the active area toward the non-active area, a size of the alignment gap being not less than 20 μm.

10. The display apparatus according to claim 1, wherein the isolation structure comprises a first isolation portion and a second isolation portion located on a side of the first isolation portion facing away from the substrate, the second isolation portion protruding from the first isolation portion toward the isolation opening.

11. A display apparatus having an active area and a non-active area, comprising:
a display panel comprising a substrate, an isolation structure, and a light-emitting device, the isolation structure being disposed on one side of the substrate and enclosing a plurality of isolation openings, and the light-emitting device being at least partially disposed within the plurality of isolation openings;
a cover plate disposed on a light-exiting side of the display panel; and
a light-shielding structure disposed on a side of the cover plate facing the display panel,
wherein the isolation structure extends from the active area to the non-active area, both the light-emitting device and the isolation opening being located in the active area, the light-shielding structure being located in the non-active area, and an orthographic projection of the light-shielding structure on the substrate and an orthographic projection of the isolation structure on the substrate enclosing an alignment gap.

12. The display apparatus according to claim 11, wherein a plurality of alignment gaps are formed, and the plurality of alignment gaps are spaced apart along a periphery of the orthographic projection of the isolation structure on the substrate,
or the orthographic projection of the light-shielding structure on the substrate is spaced apart from the orthographic projection of the isolation structure on the substrate.

13. The display apparatus according to claim 11, wherein the isolation structure further encloses a plurality of first functional openings located in the non-active area, the display apparatus further comprising a functional device at least partially located within the plurality of first functional openings, and the functional device and the light-emitting device being at least partially disposed in a same layer and made of a same material.

14. The display apparatus according to claim 11, wherein the display apparatus further comprises an auxiliary structure disposed on one side of the substrate, an orthographic projection of the auxiliary structure on the substrate being at least partially between the orthographic projection of the isolation structure on the substrate and the orthographic projection of the light-shielding structure on the substrate, and a reflectivity of the auxiliary structure being greater than that of at least a film layer structure in the isolation structure.

15. The display apparatus according to claim 14, wherein the orthographic projection of the auxiliary structure on the substrate does not overlap the orthographic projection of the isolation structure on the substrate.

16. The display apparatus according to claim 14, wherein the orthographic projection of the auxiliary structure on the substrate is spaced apart from the orthographic projection of the light-shielding structure on the substrate.

17. The display apparatus according to claim 11, wherein in a direction from the active area toward the non-active area, a size of the alignment gap is not less than 20 μm.

18. The display apparatus according to claim 11, wherein the isolation structure comprises a first isolation portion and a second isolation portion located on a side of the first isolation portion facing away from the substrate, the second isolation portion protruding from the first isolation portion toward the isolation opening.

19. A fabrication method for a display apparatus, comprising:
fabricating a display panel comprising a substrate, an isolation structure, a light-emitting device, and an auxiliary structure, both the isolation structure and the auxiliary structure being disposed on one side of the substrate, the isolation structure enclosing a plurality of isolation openings, the light-emitting device being at least partially disposed within the plurality of isolation openings, and an orthographic projection of an edge of the auxiliary structure on the substrate at least partially not overlapping an orthographic projection of the isolation structure on the substrate;
obtaining, by using an optical probe, an edge position of the auxiliary structure and an edge position of a light-shielding structure located on one side of a cover plate;
adjusting a position of the cover plate so that an orthographic projection of the light-shielding structure on the substrate and the orthographic projection of the isolation structure on the substrate enclose a desired alignment gap; and
bonding the cover plate to a light-exiting side of the display panel.
